(19) United States
(12) Patent Application Publication
(10) Pub. No.: US 2013/0087852 A1
(43) Pub. Date: Apr. 11, 2013

(54) EDGE TERMINATION STRUCTURE FOR POWER SEMICONDUCTOR DEVICES

(71) Applicants: Suku Kim, South Jordan, UT (US); Joseph Andrew Yedinak, Mountain Top, PA (US); Ihsiu Ho, Salt Lake City, UT (US)

(72) Inventors: Suku Kim, South Jordan, UT (US); Joseph Andrew Yedinak, Mountain Top, PA (US); Ihsiu Ho, Salt Lake City, UT (US)

(21) Appl. No.: 13/267,712

(22) Filed: Oct. 6, 2011

(51) Int. Cl. H01L 29/78

(52) U.S. Cl. 257/330; 257/E29.262

(57) ABSTRACT

Edge termination structures for power semiconductor devices and methods for making such structures are described. The power semiconductor devices (or power devices) contain a substrate with an epitaxial layer thereon, an array of substantially-parallel, active trenches formed in the epitaxial layer, with the active trenches containing a transistor structure with an insulated gate conducting layer, a superjunction or shielded region adjacent the active trenches; a peripheral trench surrounding the active trenches, and a source contact area within an upper surface of the epitaxial layer, where the gate conducting layer extends over the superjunction or shielded region and over the surrounding peripheral trench. Such a configuration allows the edge termination structure to be used with a wide range of breakdown voltages in power MOSFET devices containing PN superjunction structures. Other embodiments are described.

### FIELD

This application relates generally to semiconductor devices and methods for making such devices. More specifically, this application describes edge termination structures for power semiconductor devices and methods for making such structures.

### BACKGROUND

Semiconductor devices containing integrated circuits (ICs) or discrete devices are used in a wide variety of electronic apparatus. The IC devices (or chips, or discrete devices) comprise a miniaturized electronic circuit that has been manufactured in the surface of a substrate of semiconductor material. The circuits are composed of many overlapping layers, including layers containing dopants that can be diffused into the substrate (called diffusion layers) or ions that are implanted (implant layers) into the substrate. Other layers are conductors (polysilicon or metal layers) or connections between the conducting layers (via or contact layers). IC devices or discrete devices can be fabricated in a layer-by-layer process that uses a combination of many steps, including growing layers, imaging, deposition, etching, doping and cleaning Silicon wafers are typically used as the substrate and photolithography is used to mark different areas of the substrate to be doped or to deposit and define polysilicon, insulators, or metal layers.

Power semiconductor devices are often used as switches or rectifiers in electronic circuits. When connected to a circuit board, they can be used in a wide variety of apparatus including automotive electronics, disk drives and power supplies. Some power semiconductor devices can be formed in a trench that has been created in a substrate. One feature making the trench configuration attractive is that the current flows vertically through the channel of the devices in the trench. This permits a higher cell and/or current channel densities than other semiconductor devices where the current flows horizontally through the channel and then vertically through the drain. Greater cell and/or current channel densities generally mean more devices and/or current channels can be manufactured per unit area of the substrate, thereby increasing the current density of the power semiconductor device.

### SUMMARY

This application describes edge termination structures for power semiconductor devices and methods for making such structures. The power semiconductor devices (or power devices) contain a substrate with an epitaxial layer thereon, an array of substantially-parallel, active trenches formed in the epitaxial layer, with the active trenches containing a transistor structure with an insulated gate conducting layer, a superjunction or shielded region adjacent the active trenches; a peripheral trench surrounding the active trenches, and a source contact area within an upper surface of the epitaxial layer, where the gate conducting layer extends over the superjunction or shielded region and over the surrounding peripheral trench. Such a configuration allows the edge termination structure to be used with a wide range of breakdown voltages in power MOSFET devices containing PN superjunction structures.

### BRIEF DESCRIPTION OF THE DRAWINGS

The following description can be better understood in light of the Figures, in which:

FIG. 1 shows some embodiments of methods for making a semiconductor structure containing a substrate and an epitaxial (or “epi”) layer with a mask on the upper surface of the epitaxial layer;

FIG. 2 depicts some embodiments of methods for making a semiconductor structure containing two trench structures;

FIGS. 3-4 shows some embodiments of methods for making a semiconductor structure with oxide layers formed in and on the trenches;

FIG. 5 depicts some embodiments of methods for making a semiconductor structure with a gate conductor formed in the trench;

FIG. 6 shows some embodiments of methods for making a semiconductor structure with p-regions formed in the epitaxial layer;

FIGS. 7A, 7B, and 8 show some embodiments of methods for making a semiconductor structure with active trenches and peripheral trenches;

FIGS. 9 and 10 show some cross-sectional views of the semiconductor structures depicted in FIG. 8;

FIG. 11 shows a semiconductor structure containing a transition point and a source contact region; and

FIG. 12 shows some embodiments of planar semiconductor structures containing a termination structure.

The Figures illustrate specific aspects of the semiconductor devices and methods for making such devices. Together with the following description, the Figures demonstrate and explain the principles of the methods and structures produced through these methods. In the drawings, the thickness of layers and regions are exaggerated for clarity. The same reference numerals in different drawings represent the same element, and thus their descriptions will not be repeated. As the terms on, attached to, or coupled to are used herein, one object (e.g., a material, a layer, a substrate, etc.) can be on, attached to, or coupled to another object regardless of whether the one object is directly on, attached, or coupled to the other object or there are one or more intervening objects between the one object and the other object. Also, directions (e.g., above, below, top, bottom, side, up, down, under, over, upper, lower, horizontal, vertical, “x,” “y,” “z,” etc.), if provided, are relative and provided solely by way of example and for ease of illustration and discussion and not by way of limitation. In addition, where reference is made to a list of elements (e.g., elements a, b, c), such reference is intended to include any one of the listed elements by itself, any combination of less than all of the listed elements, and/or a combination of all of the listed elements.

### DETAILED DESCRIPTION

The following description supplies specific details in order to provide a thorough understanding. Nevertheless, the skilled artisan would understand that the semiconductor devices and associated methods of making and using the devices can be implemented and used without employing these specific details. Indeed, the semiconductor devices and associated methods can be placed into practice by modifying the illustrated devices and methods and can be used in conjunction with any other apparatus and techniques conventionally used in the industry. For example, while description refers to trench MOSFET devices, it could be modified for other semiconductor devices formed in trenches, such as Static Induction Transistor (SIT) devices, Static Induction Thyristor (SITh) devices, IGBT devices, BJT devices, BSIT devices, JFET devices, and thyristor devices.

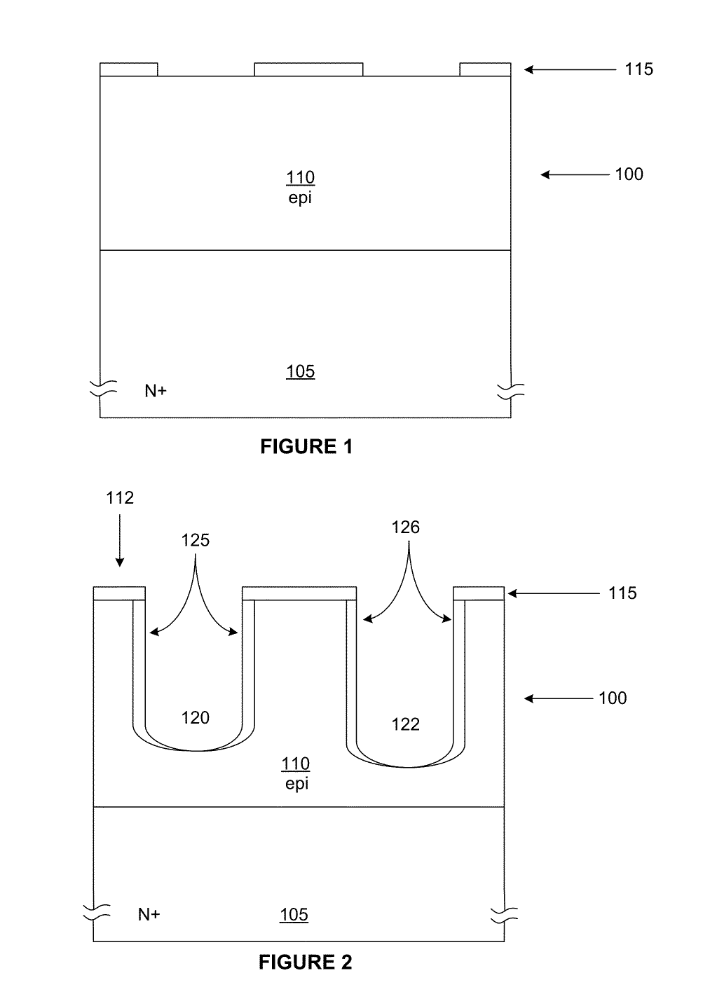

Some embodiments of the edge termination structures for power semiconductor devices and methods for making such structures are shown in FIGS. 1-11. These embodiments can be used for any number of power semiconductor devices, including those described herein. As well, these edge termination structures can be used with those semiconductor devices containing superjunction structures described in U.S. patent application Ser. Nos. 12/841,774, 12/707,323, and 12/629,232, the disclosures of which are incorporated herein by reference in their entirety.

The methods begin in some embodiments, as depicted in FIG. 1, when a semiconductor substrate 105 is first provided. Any substrate known in the art can be used in the invention. Suitable substrates include silicon wafers, epitaxial Si layers, bonded wafers such as used in silicon-on-insulator (SOI) technologies, and/or amorphous silicon layers, all of which may be doped or undoped. Also, any other semiconducting material used for electronic devices can be used, including Ge, SiGe, SiC, GaN, GaAs, InₓGa_{y}As_{z}, AlₓGa_{y}As_{z}, and/or any pure or compound semiconductors, such as III-V or II-VIs and their variants. In some embodiments, the substrate 105 can be heavily doped with any n-type dopant.

In some embodiments, the substrate 105 contains one or more epitaxial (“epi”) Si layers (individually or collectively depicted as epitaxial layer 110) located on an upper surface thereof. For example, a lightly doped p-epi layer can exist between substrate 105 and epitaxial layer 110. The epitaxial layer(s) 110 can be provided using any known process in the art, including any known epitaxial deposition process. The epitaxial layer(s) can be lightly doped with a p-type dopant.

Next, as shown in FIG. 2, a first trench structure 120 (or active trench) can be formed in the epitaxial layer 110. The bottom of the first trench 120 can reach anywhere in epitaxial layer 110 or substrate 105. The first trench structure 120 can be formed by any known process. In some embodiments, a mask 115 can be formed on the upper surface of the epitaxial layer 110. The mask 115 can be formed by first depositing a layer of the desired mask material and then patterning it using a photolithography and an etch process so the desired pattern for the mask 115 is formed. After the etching process used to create the trench 120 is complete, a mesa structure 112 has been formed between adjacent trenches 120.

The epitaxial layer 110 can then be etched by any known process until the first trench 120 has reached the desired depth and width in the epitaxial layer 110 (or substrate 105). The depth and width of the trench 120, as well as the aspect ratio of the width to the depth, can be controlled so that so a later deposited oxide layer properly fills in the trench and avoids the formation of voids. In some embodiments, the depth of the first trench structure 120 can range from about 0.1 to about 100 μm and the width can range from about 0.1 to about 50 μm. With such depths and widths, the aspect ratio of the trench can range from about 1:1 to about 1:50.

In some embodiments, a second trench structure 122 (or peripheral trench) can be formed at the same time at the first trench structure 120. In some configurations, the depth of the second trench structure 122 can be substantially the same as the depth of the first trench structure 120. In other configurations, the depth of the second trench structure 122 can be greater than the depth of the first trench structure 120. In some embodiments, the depth of the second trench structure 122 can be greater than the depth of the first trench structure up to about 100%. In other embodiments, the depth of the second trench structure 122 can be greater than the depth of the first trench structure by up to about 5%.

In some embodiments, the sidewalls of the trenches 120/122 are not perpendicular to the upper surface of the epitaxial layer 110. Instead, the angles of the trench sidewall can range from about 90 degrees (a vertical sidewall) to about 60 degrees relative to the upper surface of the epitaxial layer 110. The trench angle can be controlled so a later deposited oxide layer or any other material properly fills in the trench and avoids the formation of voids.

In some embodiments, as shown in FIG. 2, the sidewall of the first trench structure 120 can be doped with a n-type dopant so that a sidewall dopant region 125 is formed in the epitaxial layer 110 near the sidewall of the first trench 120. Optionally, the sidewall of the second trench structure 122 can also be doped with a n-type dopant so that a sidewall dopant region 126 is formed in the epitaxial layer 110 near the sidewall. The sidewall doping process can be performed using any doping process which implants the p-type dopants to the desired width. After the doping process, the dopants can be further diffused by any known diffusion or drive-in process. The width of the sidewall dopant region 125/126 can be adjusted so that the mesa 112 adjacent to any trench can be partially or fully depleted when the semiconductor device is off and the current is blocked. The presence of the sidewall dopant helps form a PN superjunction structure with a well defined PN junction, as described in some of the U.S. patent applications mentioned herein. In other configurations, the PN superjunction structure with a well defined PN junction can be formed using a thin epitaxial growth process on the sidewall, as described in some of the U.S. patent applications mentioned herein.

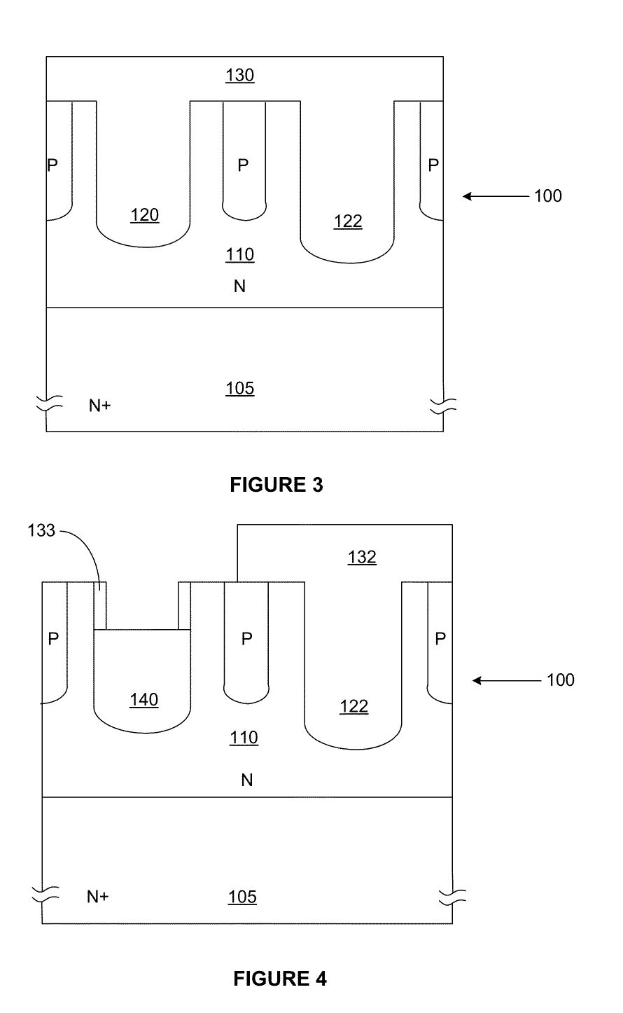

The mask 115 can be removed using any process known in the art. Then, as shown in FIG. 3, as n-type dopants diffuse from the side wall and bottom substrate, the dopant regions 125 and 126 can merge into a bottom n-type region as shown in FIG. 3. An oxide layer 130 (or other insulating or semi-insulating material) can be formed in the trenches 120/122. The oxide layer 130 can be formed by any process known in the art. In some embodiments, the oxide layer 130 can be formed by depositing an oxide material until it overflows the trenches 120/122. The thickness of the oxide layer 130 can be adjusted to any thickness needed to fill the trenches 120/122. The deposition of the oxide material can be carried out using any known deposition process, including any chemical vapor deposition (CVD) processes, such as SACVD which can produce a highly conformal step coverage within the trench. If needed, a reflow process can be used to reflow the oxide material, which will help reduce voids or defects within the oxide layer 130.

After the oxide layer 130 has been deposited, an etchback process can be used to remove the excess oxide material above and in the first trenches 120. After the etchback process, an oxide region 140 is formed in the bottom of the first trench 120, as shown in FIG. 4. A planarization process, such as any chemical and/or mechanical polishing known in the art, can be used in addition to (whether before or after) or instead of the etchback process in the regions above the first trench 120. Optionally, a high quality oxide layer can be formed prior to depositing the oxide layer 130. In these embodiments, the high quality oxide layer can be formed by oxidizing the epitaxial layer 110 in an oxide-containing atmosphere until the desired thickness of the high-quality oxide layer has been grown. The high quality oxide layer can be used to improve the oxide integrity and filling factor, thereby making the oxide layer 130 a better insulator.

With the second trench structures 122, however, no removal process for the oxide layer 130 is performed. Rather, the oxide layer 130 remains in and above the second trenches 122, as shown in FIG. 4 and forms an oxide layer 132. In some embodiments, the thickness of the oxide layer 132 can range up to about 5 μm. In other embodiments, the thickness of the oxide layer 132 can range up to about 5000 Å.

After formation of the bottom oxide region 140 in first trenches 120, a gate insulating layer (such as a gate oxide layer 133) can be grown on the exposed sidewalls of the trench 120 that are not covered by the bottom oxide layer 140, as shown in FIG. 4. The gate oxide layer 133 can be formed by any process which oxidizes the exposed silicon in the sidewalls of the trench 120 until the desired thickness is grown. No gate insulating layer is formed in the second trenches 122.

Subsequently, a conductive layer can be deposited in the middle or upper part of the trenches 120 and on the bottom oxide region 140. The conductive layer can comprise any conductive and/or semiconductive material known in the art including any metal, silicide, semiconducting material, doped polysilicon, or combinations thereof. This conductive layer can be deposited by any known deposition process, including chemical vapor deposition processes (CVD, PECVD, LPCVD, etc.) or sputtering processes using the desired metal as the sputtering target. In some configurations, the conductive layer extends over part of the oxide layer 132 above the second trenches 122, as explained in more detail below.

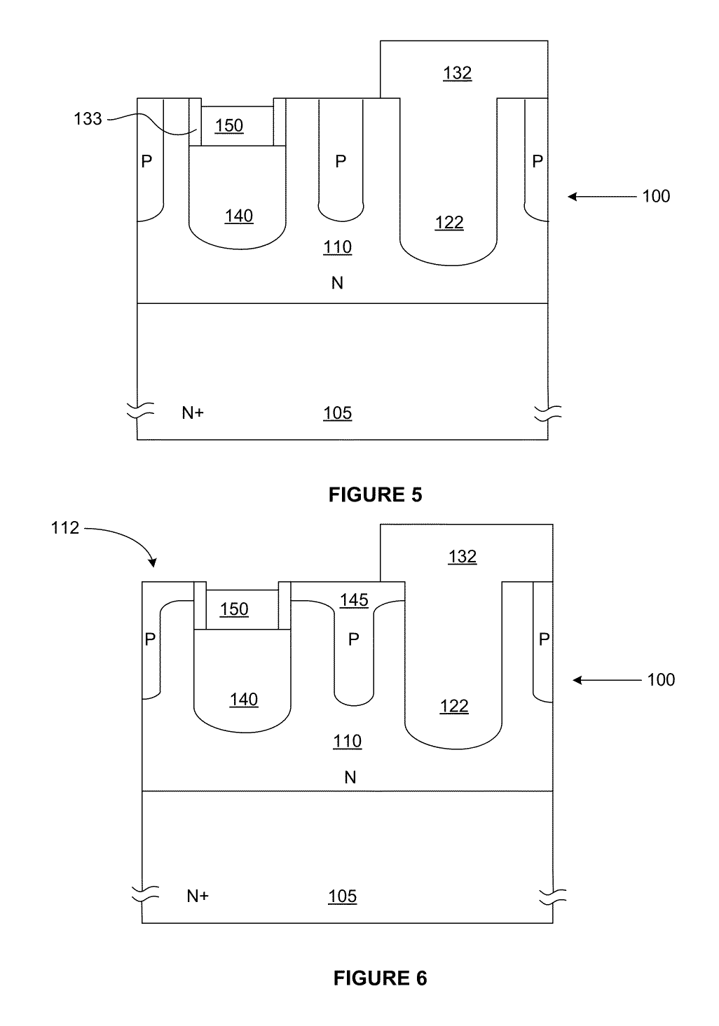

The conductive layer can be deposited so that it fills and overflows over the upper part of the first trenches 120. Then, a gate 150 (or gate conductor) can be formed from the conductive layer using any process known in the art. In some embodiments, the gate 150 can be formed by removing the upper portion of the conductive layer using any process known the art, including any etchback process. The result of the removal process leaves a conductive layer (the gate 150) overlying the first oxide region 140 in the trench 120 and sandwiched between the gate oxide layers 133, as shown in FIG. 5. In some configurations, the gate conductor can be formed so that its upper surface is substantially planar with the upper surface of the epitaxial layer 110.

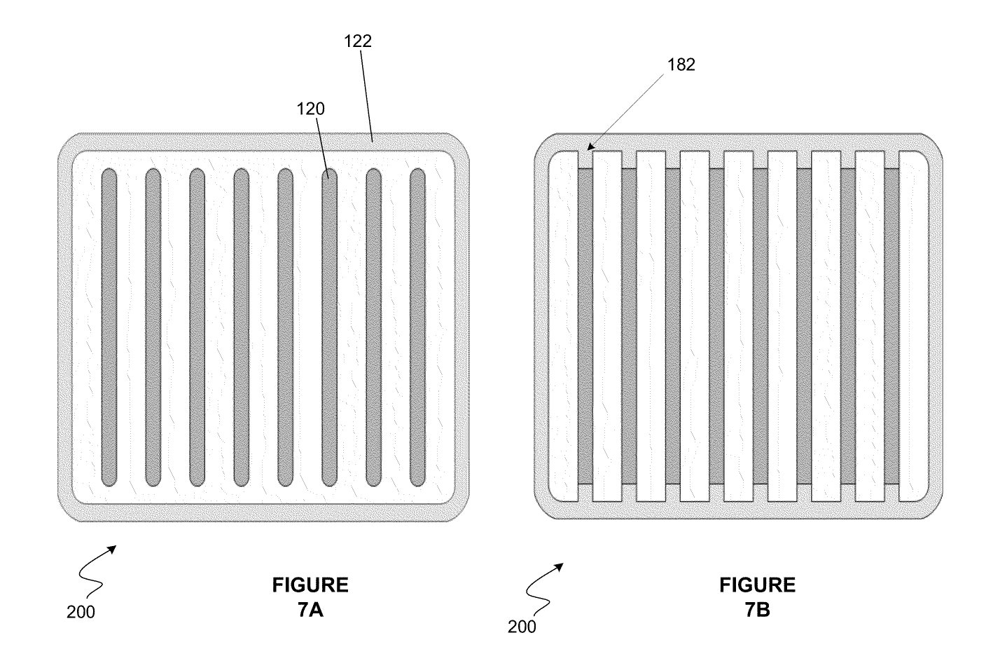

Then, a p-type dopant region 145 can be formed in an upper portion of the epitaxial layer 110, as shown in FIG. 6. The p-type dopant region 145 can be formed using any process known in the art. In some embodiments, the p-dopant regions 145 can be formed by implantation and then a diffusion process, which diffuses the p-type dopants from the implanted region.

The remainder of the transistor (i.e., MOSFET) structure can then be formed in the first trenches 120 using any processing known in the art. No MOSFET structure is formed in the second trenches 122. In some embodiments, the MOSFET structure can be completed by forming contact regions on the exposed upper surface of the epitaxial layer 110. Then, the upper surface of the gate is covered with an overlying insulating layer and used to form an insulation cap. Then, the contact region and the p-dopant region 145 can be etched to form an insert region. A source layer (or region) can then be deposited over the upper portions of the insulation cap and the contact region. And after (or before) the source layer has been formed, a drain can be formed on the backside of the substrate using any process known in the art.

These methods can form the semiconductor structures 200 shown in FIGS. 7A and B. The other device components are not depicted in the top views, FIGS. 7A and B so that the trench structures can be clearly seen. As depicted in FIG. 7A, the semiconductor structure 200 contains a series of first, active trenches 120 that extend substantially parallel to each other and that contain an active channel region therein. The semiconductor structure 200 also contains second trench 122 that forms a periphery or ring around the series of trenches 120. While only a single second trench 122 is shown in FIG. 7A, additional trenches 122 can be formed so that successive ring-shaped peripheral trenches can be formed. FIG. 7B shows other embodiments wherein the peripheral trench structure contains a protrusion 182 which can extend to abut the active trenches 120.

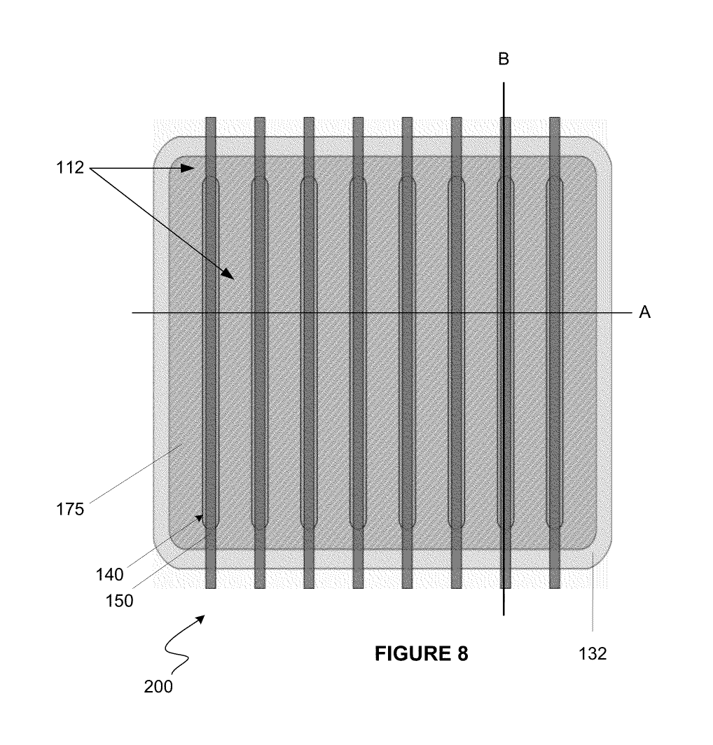

FIG. 8 shows the semiconductor structure 200 with some of the MOSFET components illustrated therein. In the top view shown in FIG. 8, the active trenches 120 contain an insulating layer 140 formed in the active trenches 120. A depleted region 175 is located adjacent the active trenches 120. The depleted region 175 contains the PN superjunction structure and a shielded region. The peripheral trench 122 also contains the insulating layer 132 formed in and on the trenches 122. The gate conducting line 150 is formed on the insulating layer 140, yet within the active trenches 120. The gate conducting lines 150 extend above the mesa structures 112 and over the perimeter trench 122 so that it can be connected to a gate bus, as known in the art.

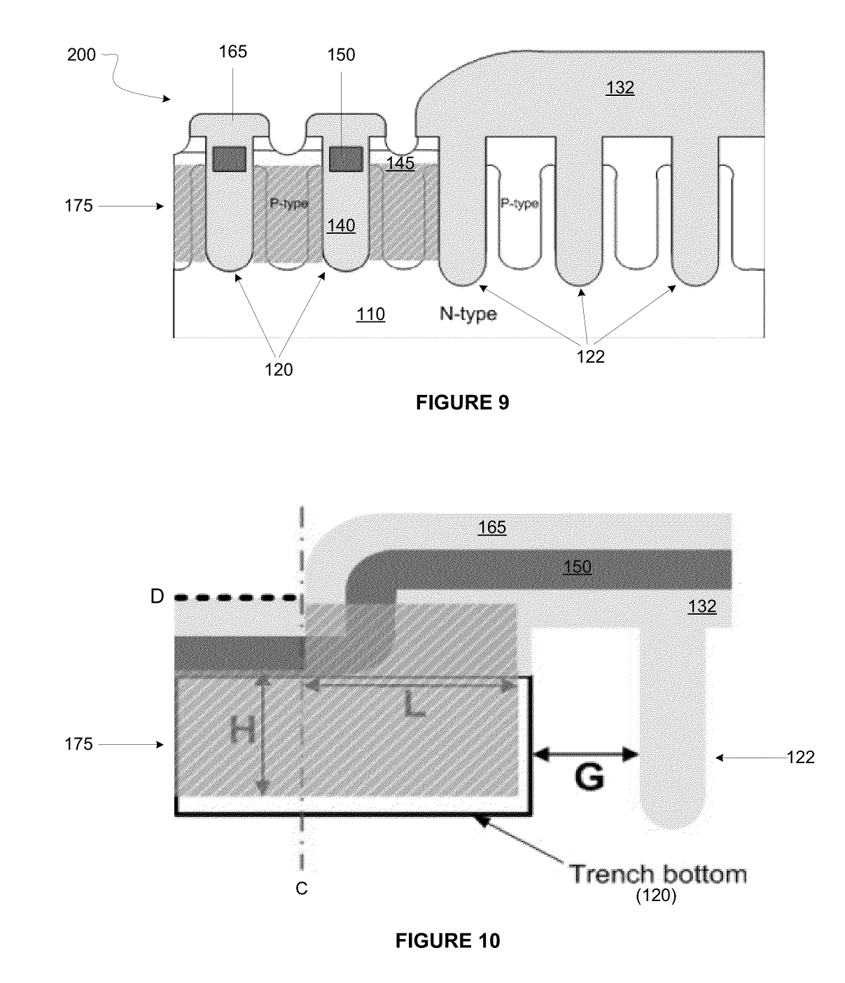

A cross-section of the semiconductor structure 200 along line A of FIG. 8 is illustrated in FIG. 9. The semiconductor structure 200 contains first trenches 120 with oxide layer 140, gate 150, and an overlying insulation cap 165. A depleted region 175 (with the PN superjunction structure and the shielded region) is formed in the epitaxial layer 110 near the MOSFET structures in active trenches 120 when the device is operated. P-dopant regions 145 have been formed in the upper portion of the epitaxial layer 110.

The semiconductor structure 200 contains multiple second (peripheral) trenches 122 filled with insulating layer 132. In some configurations, the peripheral trenches 122 can contain a dielectric material, an insulator, a semi-insulator, a conductor, or a combination thereof.

The number of peripheral trenches 122 in the semiconductor structure 200 depends on the voltage ratings and the required leakage performance of the device. In some embodiments, the number of second trenches 122 can range up to 50. In other embodiments, the number of second trenches 122 ranges from 1 to 10. In yet other embodiments, the number of second trenches 122 is about 5. When more than one perimeter trench 122 is used, the voltage can be spread out laterally.

A cross-section of the semiconductor structure 200 along line B of FIG. 8 is illustrated in FIG. 10. As shown in this Figure, the end of the first (active) trench 120 is separated from the adjacent sidewall of the second (perimeter) trench 122 by a gap G. This distance of this gap G depends on how to optimize the charge balance effect around the region and breakdown voltage rating. In some embodiments, the distance of this gap G can range from about 0 (where the two trenches contact each other as shown in FIG. 7B) to about 1000 μm. In other embodiments, the distance of this gap G can range up to about 10 μm. In yet other embodiments, the distance of this gap G can range up to about 1 μm.

As shown in FIG. 10, the depleted region 175 contains sections with a height H (i.e., the vertical depletion length) and a length L (i.e., the horizontal depletion length). The distance of length L and height H should be large enough for the depleted region to extend and sustain the breakdown voltage. In some embodiments, the distance of length L should be equal or greater than height H. The depth of the perimeter trenches 122 can be equal or larger than the trenches 120 in the active area, thereby ensuring an equal or higher breakdown voltage for the edge termination area than the active area.

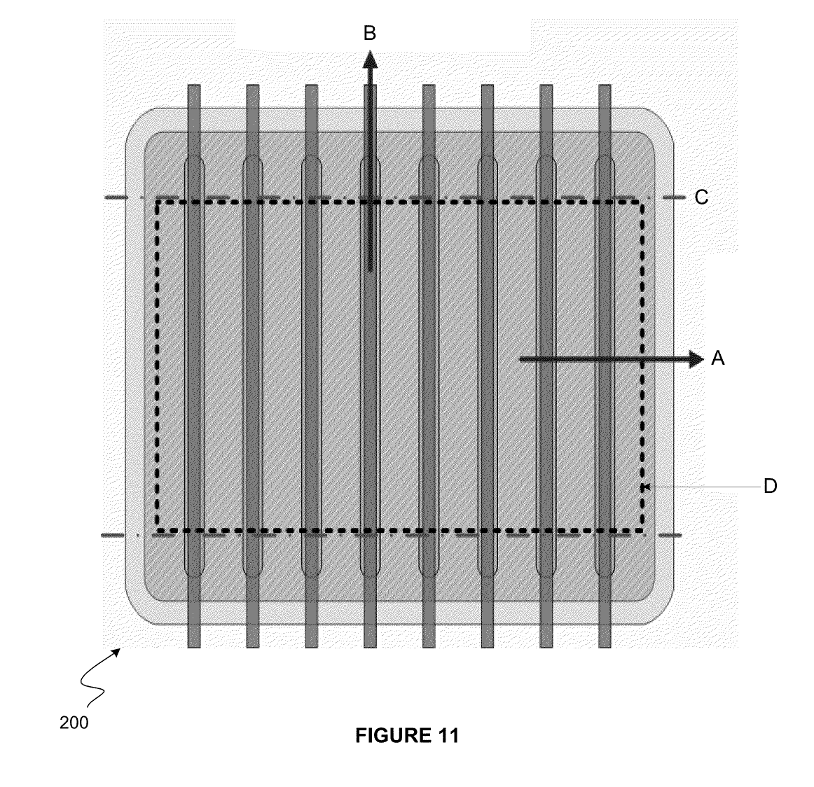

The semiconductor structure 200 also contains a transition point (shown by line C) and source contact area (shown by line D). The transition point is that location in the structure at which the gate conducting line 150 extends above the mesa surface and continues over the second, perimeter trench 122 so it can be connected to the gate bus (not shown). A top view of the transition point (line C) is depicted in FIG. 11.

As shown in both FIGS. 10 and 11, the semiconductor structure 200 contains a source contact area D. The source contact area D can be configured within a specific region of the structure 200 so that the superjunction or shielded area can be sufficiently extended to support the breakdown voltage adjacent to the end of the trenches. In some configurations, the distance (L) between the edge of the source region and the end of the depletion region (formed by the superjunction structure) can be sufficient to block the breakdown voltage. Hence, the distance L in these configurations should be equal to or larger than the distance H.

These methods of manufacturing and the devices formed have several useful features. The semiconductor devices described in the U.S. patent applications detailed above contain PN superjunctions in MOSFET, SIT, and JFET devices, as described therein. The edge termination designs described herein can be used with numerous SIT, JFET, and MOSFET architectures that contain superjunction structures, shielded structures, and various reduced surface field (resurf) structures. Further, the termination designs described herein can be used in a wide range of breakdown voltage ratings (low to high voltage) with only one design (and only one method needed to make that design).

The termination methods described above can also reduce the non-active area of the conventional termination regions used for superjunction devices. P/N superjunction MOSFET devices typically require termination regions that contain multiple P and N rings in the peripheral region. But such a configuration consumes significant area in the non-active region.

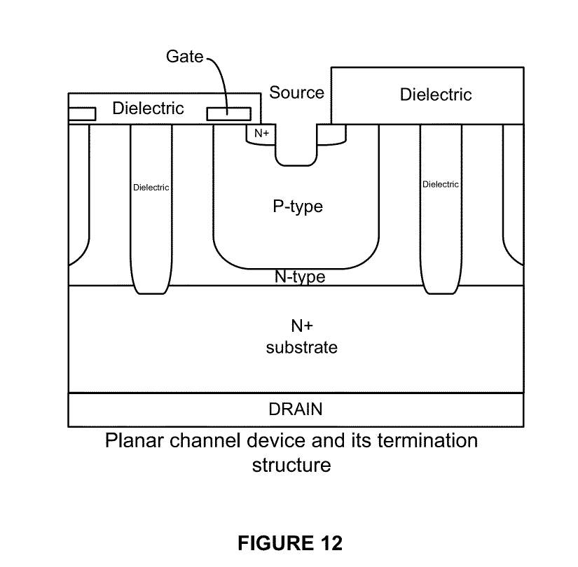

The description above describes using the termination structures and methods in a vertical channel MOSFET. In other configurations, though, the termination structures and methods can be used in a planar channel MOSFET device, similar to the vertical channel MOSFET case except that the gate structure can be made on the mesa surface as shown in FIG. 12.

In some embodiments, the application relates to methods for making a semiconductor structures comprising: providing a semiconductor substrate with an epitaxial layer thereon; providing an array of substantially-parallel, active trenches formed in the epitaxial layer, where the trenches contain a transistor structure with an insulated gate conducting layer; providing a superjunction or shielded region adjacent the active trenches; providing a peripheral trench surrounding the active trenches; and providing a source contact area within an upper surface of the epitaxial layer; where the gate conducting layer extends over the superjunction or shielded region and over the surrounding peripheral trench.

In some embodiments, the application relates to methods for making a semiconductor structures comprising: forming an epitaxial layer on a semiconductor substrate; etching an array of substantially-parallel, active trenches in the epitaxial layer; forming a transistor structure with an insulated gate conducting layer in the active trenches; providing a superjunction, shielded region, or resurf structures adjacent the active trenches; etching a peripheral trench to surround the active trenches; and doping an upper surface of the epitaxial layer to provide a source contact area; where the gate conducting layer extends over the superjunction or shielded region and over the surrounding peripheral trench.

In addition to any previously indicated modification, numerous other variations and alternative arrangements may be devised by those skilled in the art without departing from the spirit and scope of this description, and appended claims are intended to cover such modifications and arrangements. Thus, while the information has been described above with particularity and detail in connection with what is presently deemed to be the most practical and preferred aspects, it will be apparent to those of ordinary skill in the art that numerous modifications, including, but not limited to, form, function, manner of operation and use may be made without departing from the principles and concepts set forth herein. Also, as used herein, examples are meant to be illustrative only and should not be construed to be limiting in any manner.

1. A semiconductor structure, comprising:
a semiconductor substrate with an epitaxial layer thereon;
an array of substantially-parallel, active trenches formed in the epitaxial layer, the trenches containing a transistor structure with an insulated gate conducting layer;
a superjunction or shielded region adjacent the active trenches;
a peripheral trench surrounding the active trenches, the peripheral trench containing a dielectric material, an insulator, a semi-insulator, a conductor, or a combination thereof; and
a source contact area within an upper surface of the epitaxial layer;
wherein the gate conducting layer extends over the superjunction or shielded region and over the surrounding peripheral trench.

2. The structure of claim 1, wherein the peripheral trench is deeper than the active trench array.

3. The structure of claim 1, further comprising multiple peripheral trenches.

4. The structure of claim 4, further comprising up to 50 peripheral trenches.

5. The structure of claim 1, wherein the gap between an end of the line trench array and the perimeter trench ranges up to about 1000 μm.

6. The structure of claim 5, wherein the gap ranges up to about 10 μm.

7. The structure of claim 1, wherein the peripheral trench contains protrusions abutting the end of the active trenches.

8. A power semiconductor device, comprising:
a semiconductor substrate heavily doped with a dopant of a first conductivity type;
an epitaxial layer on the substrate, the epitaxial layer being lightly doped with a dopant of the first conductivity type;
an array of substantially-parallel, active trenches formed in the epitaxial layer, the trenches containing a first insulating layer on the bottom and sidewall of the trenches, a gate conducting layer formed on the first insulating layer, and a second insulating layer over the gate conducting layer, wherein both sides of the actives trenches have been doped with a dopant of a second conductivity type to form a superjunction structure;
a peripheral trench surrounding the active trenches;
a source contact area within an upper surface of the epitaxial layer; and
a drain on the bottom of the substrate;
wherein the gate conducting layer extends over the superjunction region and over the surrounding peripheral trench.

9. The device of claim 8, wherein the peripheral trench is deeper than the active trench array.

10. The device of claim 8, further comprising multiple peripheral trenches.

11. The device of claim 10, further comprising up to 50 peripheral trenches.

12. The device of claim 8, wherein the gap between an end of the line trench array and the perimeter trench ranges up to about 1000 μm.

13. The device of claim 8, wherein the peripheral trench contains protrusions abutting the end of the active trenches.

14. The device of claim 8, wherein the peripheral trench contains a dielectric material, an insulator, a semi-insulator, a conductor, or a combination thereof.

15. The device of claim 8, wherein the power semiconductor device contains a vertical channel MOSFET, SIT, or JFET device.

16. An electronic apparatus, comprising:
a circuit board; and
a power MOSFET semiconductor device connected to the circuit board, the semiconductor device containing:
a semiconductor substrate heavily doped with a dopant of a first conductivity type;
an epitaxial layer on the substrate, the epitaxial layer being lightly doped with a dopant of the first conductivity type;
an array of substantially-parallel, active trenches formed in the epitaxial layer, the trenches containing a first insulating layer on the bottom and sidewall of the trenches, a gate conducting layer formed on the first insulating layer, and a second insulating layer over the gate conducting layer, wherein both sides of the actives trenches have been doped with a dopant of a second conductivity type to form a superjunction structure;
a peripheral trench surrounding the active trenches;
a source contact area within an upper surface of the epitaxial layer; and
a drain on the bottom of the substrate;
wherein the gate conducting layer extends over the superjunction region and over the surrounding peripheral trench.

17. The apparatus of claim 16, wherein the peripheral trench is deeper than the active trench array.

18. The apparatus of claim 16, further comprising multiple peripheral trenches.

19. The apparatus of claim 16, wherein the gap between an end of the line trench array and the perimeter trench ranges up to about 1000 μm.

20. The apparatus of claim 16, wherein the peripheral trench contains a dielectric material, an insulator, a semi-insulator, a conductor, or a combination thereof.
